(19) United States
(12) Patent Application Publication
(10) Pub. No.: US 2025/0159874 A1
(43) Pub. Date: May 15, 2025

(54) ONE-TIME PROGRAMMABLE MEMORY STRUCTURE AND ONE-TIME PROGRAMMABLE MEMORY ARRAY

(71) Applicant: UNITED MICROELECTRONICS CORP, Hsin-chu City (TW)

(72) Inventors: Chang-Yih Chen, Tainan City (TW); Kuo-Hsing Lee, Hsinchu County (TW); Chun-Hsien Lin, Tainan City (TW)

(73) Assignee: UNITED MICROELECTRONICS CORP, Hsin-Chu City (TW)

(21) Appl. No.: 18/531,696

(22) Filed: Dec. 7, 2023

(30) Foreign Application Priority Data
Nov. 14, 2023 (TW) 112143770

(51) Int. Cl. H10B 20/25

(52) U.S. Cl. CPC H10B 20/25

(57) ABSTRACT

A one-time programmable memory structure includes semiconductor substrate of a first conductivity type and a fin disposed on the semiconductor substrate. The fin extends along a first direction, wherein the fin includes a first portion and a second portion that is contiguous with the first portion. The first portion and the second portion have different cross-sectional profiles. A gate extends on the fin along a second direction. The gate partially overlaps the first portion of the fin and partially overlaps the second portion of the fin.

### BACKGROUND OF THE INVENTION

### 1. Field of the Invention

The present invention relates to the field of semiconductor technology, and in particular to a one-time programmable (OTP) memory structure and a memory array.

### 2. Description of the Prior Art

The storage state of the OTP memory cell of the OTP memory device is determined after being programmed, and the storage state of the OTP memory cell cannot be changed.

In general, OTP memory cells can be divided into two types: fuse OTP memory cells and anti-fuse OTP memory cells. For example, when the antifuse OTP memory cell is not programmed, it is in a high impedance storage state. When the antifuse OTP memory cell is programmed, it is in a low impedance state. For example, when the fuse OTP memory cell is not programmed, it is in a low impedance storage state. When the fuse OTP memory cell is programmed, it is in a high impedance state.

### SUMMARY OF THE INVENTION

It is one object of the present invention to provide an improved single transistor (IT) one-time programmable (OTP) memory structure and memory array, which can be compatible with fin field effect transistors (finFETs) at 14 nanometer node or below and has better program efficiency.

One aspect of the invention provides a one-time programmable (OTP) memory structure including a semiconductor substrate of a first conductivity type; a fin disposed on the semiconductor substrate, wherein the fin extends along a first direction, wherein the fin comprises a first portion and a second portion that is contiguous with the first portion, and wherein the first portion and the second have different cross-sectional profiles; and a gate extending over the fin along a second direction, wherein the gate partially overlaps with the first portion of the fin and partially overlaps with the second portion of the fin.

According to some embodiments, the OTP memory structure further includes a first gate dielectric layer between the gate and the first portion of the fin; and a second gate dielectric layer between the gate and the second portion of the fin, wherein the first gate dielectric layer and the second gate dielectric have different thicknesses.

According to some embodiments, the first gate dielectric layer is thicker than the second gate dielectric layer.

According to some embodiments, a step is disposed between the first gate dielectric layer and the second gate dielectric layer.

According to some embodiments, the first gate dielectric layer is an input/output (I/O) oxide layer and has a thickness of 25-45 angstroms, and wherein the second dielectric layer is a core oxide layer and has a thickness of 5-25 angstroms.

According to some embodiments, the first portion of the fin has a first top width and the second portion of the fin has a second top width, wherein the first top width is greater than the second top width.

According to some embodiments, the first portion of the fin has the first conductivity type, and the second portion of the fin has a second conductivity type opposite to the first conductivity type.

According to some embodiments, the first conductivity type is P type and the second conductivity type is N type.

According to some embodiments, the first portion of the fin has a rectangular-shaped cross-sectional profile, and wherein the second portion of the fin has a conical tip-shaped cross-sectional profile and a sidewall surface with at least two different slopes.

According to some embodiments, the gate is a metal gate.

Another aspect of the invention provides a one-time programmable (OTP) memory array including a semiconductor substrate of a first conductivity type; a plurality of fins disposed on the semiconductor substrate, wherein the plurality of fins extends along a first direction, wherein each of the plurality of fin comprises a first portion and a second portion that is contiguous with the first portion, and wherein the first portion and the second have different cross-sectional profiles; and at least one gate extending over the plurality of fins along a second direction, wherein the plurality of gates gate partially overlaps with the first portion and partially overlaps with the second portion.

According to some embodiments, the OTP memory array further includes a first gate dielectric layer between the at least one gate and the first portion; and a second gate dielectric layer between the at least one gate and the second portion, wherein the first gate dielectric layer and the second gate dielectric have different thicknesses.

According to some embodiments, the first gate dielectric layer is thicker than the second gate dielectric layer.

According to some embodiments, a step is disposed between the first gate dielectric layer and the second gate dielectric layer.

According to some embodiments, the first gate dielectric layer is an input/output (I/O) oxide layer and has a thickness of 25-45 angstroms, and wherein the second dielectric layer is a core oxide layer and has a thickness of 5-25 angstroms.

According to some embodiments, the first portion has a first top width and the second portion has a second top width, wherein the first top width is greater than the second top width.

According to some embodiments, the first portion has the first conductivity type, and the second portion has a second conductivity type opposite to the first conductivity type.

According to some embodiments, the first conductivity type is P type and the second conductivity type is N type.

According to some embodiments, the first portion has a rectangular-shaped cross-sectional profile, and wherein the second portion of the fin has a conical tip-shaped cross-sectional profile and a sidewall surface with at least two different slopes.

According to some embodiments, the at least one gate is a metal gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a partial schematic diagram of a one-time programmable memory structure according to an embodiment of the present invention.

FIG. 2 is a schematic cross-sectional view taken along line I-I′ in FIG. 1.

FIG. 3 is a schematic cross-sectional view along line II-II′ in FIG. 1.

FIG. 4 is a schematic cross-sectional view along line III-III′ in FIG. 1.

FIG. 5 is a schematic diagram of a partial layout of a one-time programmable memory array according to another embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

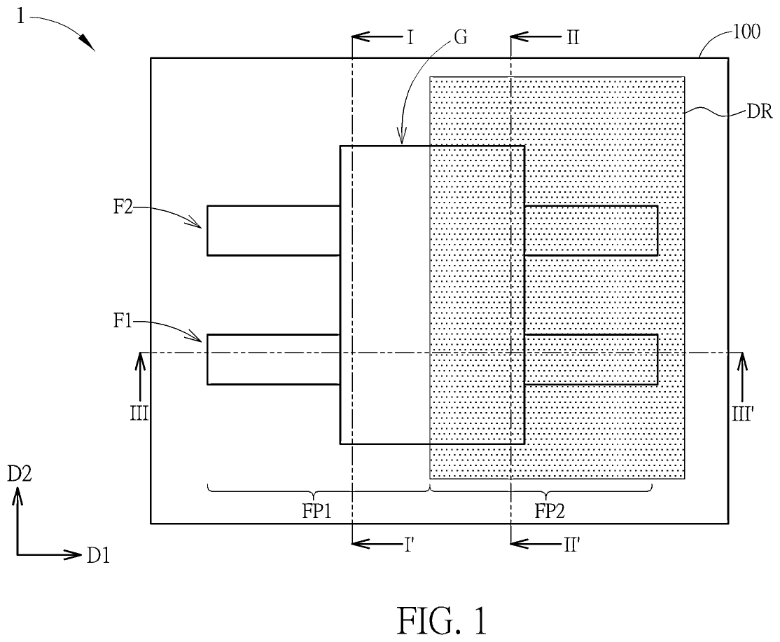

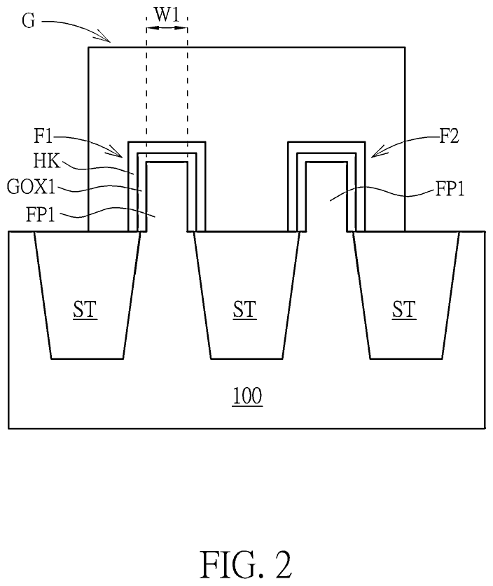

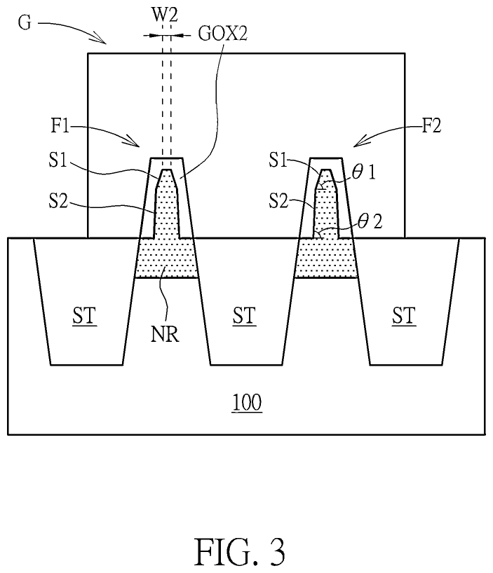

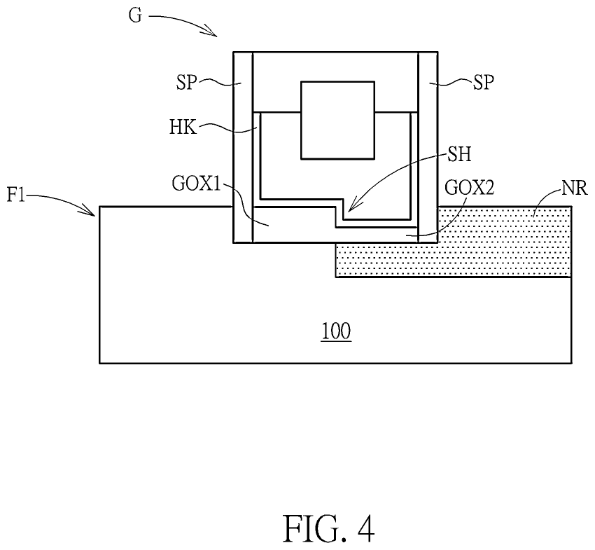

Please refer to FIG. 1 to FIG. 4, wherein FIG. 1 is a partial schematic diagram of a one-time programmable (OTP) memory structure according to an embodiment of the present invention, FIG. 2 is a schematic cross-sectional view taken along line II′ in FIG. 1, FIG. 3 is a schematic cross-sectional view taken along line II-II′ in FIG. 1, and FIG. 4 is a schematic cross-sectional view taken along line III-III′ in FIG. 1.

As shown in FIG. 1 to FIG. 4, the OTP memory structure 1 includes a semiconductor substrate 100 of a first conductivity type. For example, the first conductivity type is P type, and the semiconductor substrate 100 may be a silicon substrate. Fins F1 and F2 are provided on the semiconductor substrate 100, wherein the fins F1 and F2 extend along the first direction D1. According to an embodiment of the present invention, a trench isolation structure ST is further provided on the semiconductor substrate 100. The fins F1 and F2 protrude from the top surface of the trench isolation structure ST.

According to an embodiment of the present invention, each of the fins F1 and F2 includes a first portion FP1 and a second portion FP2 that is contiguous with the first portion FP1. According to an embodiment of the present invention, the first portion FP1 has a first conductivity type, and the second portion FP2 has a second conductivity type that is opposite to the first conductivity type.

According to an embodiment of the invention, the first portion FP1 and the second portion FP2 have different cross-sectional profiles. According to an embodiment of the present invention, as shown in FIG. 2, for example, the first portion FP1 of each of the fins F1 and F2 has a rectangular (or approximately rectangular) cross-sectional profile. According to an embodiment of the present invention, as shown in FIG. 3, for example, the second portion FP2 of each of the fins F1 and F2 has a pointed tapered cross-sectional profile or conical tip-shaped cross-sectional profile.

According to an embodiment of the present invention, as shown in FIG. 3, the sidewall surfaces of the second portion FP2 of the fins F1 and F2 have at least two different slopes, for example, a first sidewall surface S1 with a first slope and a second sidewall surface S2 with a second slope, wherein the first slope is smaller than the second slope. According to an embodiment of the present invention, the first sidewall surface S1 is directly connected to the second sidewall surface S2. According to an embodiment of the invention, the first sidewall surface S1 is the upper sidewall surface and the second sidewall surface S2 is the lower sidewall surface. According to an embodiment of the present invention, for example, the angle θ1 between the first sidewall surface S1 and the horizontal plane is approximately 78°, and the angle θ2 between the second sidewall surface S2 and the horizontal plane is approximately 83°.

According to an embodiment of the present invention, as shown in FIG. 2 and FIG. 3, the first portion FP1 of each of the fins F1 and F2 has a first top width w1 and the second portion FP2 of each of the fins F1 and F2 has a second top width w2, wherein the first top width w1 is greater than the second top width w2.

As shown in FIG. 1, the semiconductor substrate 100 further includes a counter doping capacitor region DR. A second conductive type dopant, for example, an N-type dopant, is implanted into the counter-doping capacitor region DR to form an N-type doped region. According to an embodiment of the present invention, the second portion FP2 of each of the fins F1 and F2 is located in the counter-doping capacitor region DR. Therefore, the second portion FP2 of each of the fins F1 and F2 has a second conductivity type, for example, N type. For example, as shown in FIG. 4, the second portion FP2 of each of the fins F1 and F2 has an N-type doped region NR.

According to an embodiment of the present invention, the OTP memory structure 1 further includes a gate G extending on the fins F1 and F2 along the second direction D2, wherein the gate G partially overlaps with the first portion FP1 of each of the fins F1 and F2 FP1 and partially overlaps with the second portion FP2 of each of the fins F1 and F2. As shown in FIG. 1, the gate G covers the interface between the first portion FP1 and the second portion FP2.

According to an embodiment of the present invention, the gate G is, for example, a metal gate. According to an embodiment of the present invention, the gate G may further include a high dielectric constant material layer HK. According to an embodiment of the present invention, as shown in FIG. 4, a sidewall spacer SP may be provided on the sidewall of the gate G. The detailed structure of the gate G is known as that of a typical fin field effect transistor and is therefore omitted herein.

According to an embodiment of the present invention, the OTP memory structure 1 further includes a first gate dielectric layer GOX1 located between the gate G and the first portion FP1 of each of the fins F1 and F2. According to an embodiment of the present invention, the OTP memory structure 1 further includes a second gate dielectric layer GOX2 located between the gate G and the second portion FP2 of each of the fins F1 and F2. The first gate dielectric layer GOX1 and the second gate dielectric layer GOX2 have different thicknesses. According to an embodiment of the present invention, the first gate dielectric layer GOX1 is thicker than the second gate dielectric layer GOX2.

According to an embodiment of the present invention, for example, the first gate dielectric layer GOX1 may be an input/output (I/O) oxide layer (formed simultaneously with the gate dielectric layer of the I/O devices) and have a thickness of 25-45 angstroms, and the second gate dielectric layer GOX2 may be a core oxide layer (formed simultaneously with the gate dielectric layer of the core logic devices) and has a thickness of 5-25 angstroms.

According to an embodiment of the present invention, a step SH is disposed between the first gate dielectric layer GOX1 and the second gate dielectric layer GOX2 with different thicknesses. According to an embodiment of the present invention, the step SH forms a corner structure or a sharper corner at the bottom of the gate G. This corner structure can generate a higher electric field during programming operations and improve programming efficiency.

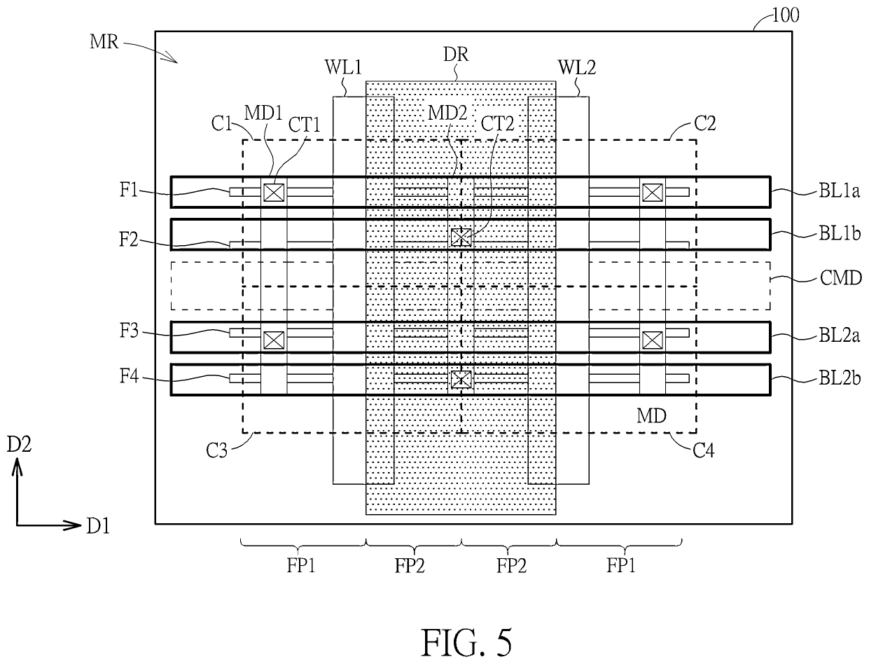

Please also refer to FIG. 5, which is a schematic diagram of a partial layout of an OTP memory array according to another embodiment of the present invention. For the sake of simplicity, a 2×2 memory array including four unit memory cells C1-C4 of the OTP memory array MR is shown in FIG. 5. The four unit memory cells C1-C4 are arranged in a mirror image configuration. For example, the unit memory cell C1 and the unit memory cell C2 have a mirror symmetrical structure, and the unit memory cell C3 and the unit memory cell C4 have a mirror symmetrical structure. The detailed structure of each unit memory cell C1-C4 in FIG. 5 can be seen in FIG. 1 to FIG. 4.

As shown in FIG. 5, the OTP memory array MR is formed on the semiconductor substrate 100 having a first conductivity type, for example, P type. A plurality of fins is provided on the semiconductor substrate 100, for example, fins F1-F4. The fins F1-F4 extend along the first direction D1. Likewise, each of the fins F1-F4 includes a first portion FP1 and a second portion FP2 that is contiguous with the first portion FP1, as set forth in FIG. 1 to FIG. 4.

Likewise, the first portion FP1 and the second portion FP2 have different cross-sectional profiles, the details of which are as shown in FIG. 1 to FIG. 4. According to an embodiment of the present invention, the first portion FP1 has a first conductivity type, for example, P type, and the second portion FP2 has a second conductivity type, for example, N type. According to an embodiment of the present invention, the first portion FP1 has a rectangular cross-sectional profile, as shown in FIG. 2, and the second portion FP2 has a pointed conical cross-sectional profile and its sidewall surface has at least two different slopes, as shown in FIG. 3.

According to an embodiment of the present invention, as shown in FIG. 2, for example, the first portion FP1 has a rectangular (or nearly rectangular) cross-sectional profile. According to an embodiment of the present invention, as shown in FIG. 3, for example, the second portion FP2 has a or conical tip-shaped cross-sectional profile.

According to an embodiment of the present invention, as shown in FIG. 3, the sidewall surface of the second portion FP2 has at least two different slopes, for example, a first sidewall surface S1 with a first slope and a second sidewall surface S2 with a second slope, wherein the first slope is smaller than the second slope. According to an embodiment of the present invention, the first side wall surface S1 is directly connected to the second side wall surface S2. According to an embodiment of the invention, the first sidewall surface S1 is the upper sidewall surface and the second sidewall surface S2 is the lower sidewall surface. According to an embodiment of the present invention, for example, the angle θ1 between the first sidewall surface S1 and the horizontal plane is approximately 78°, and the angle θ2 between the second sidewall surface S2 and the horizontal plane is approximately 83°.

According to an embodiment of the present invention, as shown in FIG. 2 and FIG. 3, the first portion FP1 has a first top width w1 and the second portion FP2 has a second top width w2, wherein the first top width w1 is greater than the second top width w2.

As shown in FIG. 5, the OTP memory array MR further includes a counter-doping capacitor region DR. A second conductive type dopant, for example, an N-type dopant, is implanted into the counter-doping capacitor region DR to form an N-type doped region. According to an embodiment of the present invention, the second portion FP2 is located in the counter-doping capacitor region DR, and therefore, the second portion FP2 has the second conductivity type, for example, N type. For example, as shown in FIG. 4, the second portion FP2 has an N-type doped region NR.

According to an embodiment of the present invention, as shown in FIG. 5, a plurality of contact strips, such as contact strips MD1-MD3, may be provided on the semiconductor substrate 100 along the second direction D2, for locally electrically connecting the fins F1-F4. According to an embodiment of the present invention, the plurality of contact strips may be formed of a zeroth layer of metal (or M0 layer). According to an embodiment of the present invention, a contact strip cutting region CMD may be provided along the first direction D1 on the semiconductor substrate 100 for cutting the contact strip MD.

According to an embodiment of the present invention, as shown in FIG. 5, a plurality of word lines (or gates) may be provided on the semiconductor substrate 100, for example, word lines WL1 and WL2, extend along the second direction D2 on the fin F1-F4, wherein the word lines WL1, WL2 partially overlap the first portions FP1 and partially overlap the second portions FP2. According to an embodiment of the present invention, the word lines WL1 and WL2 are, for example, metal gates.

According to an embodiment of the present invention, as shown in FIG. 2 to FIG. 4, the OTP memory array MR further includes a first gate dielectric layer GOX1 located between the gate G and the first portion FP1, and a second gate dielectric layer GOX2 located between the gate G and the second portion FP2. The first gate dielectric layer GOX1 and the second gate dielectric layer GOX2 have different thicknesses. For example, the first gate dielectric layer GOX1 is thicker than the second gate dielectric layer GOX2. According to an embodiment of the present invention, the first gate dielectric layer GOX1 may be an input/output oxide layer with a thickness of 25-45 angstroms, and the second gate dielectric layer GOX2 may be a core oxide layer with a thickness of 5-25 angstroms. A step SH is disposed between the first gate dielectric layer GOX1 and the second gate dielectric layer GOX2 with different thicknesses.

According to an embodiment of the present invention, the OTP memory array MR further includes a plurality of bit lines, such as a bit line BL1a, a bit line BL1b, a bit line BL2a, and a bit line BL2b, extending along the first direction D1. According to an embodiment of the present invention, bit lines BL1a, BL1b, BL2a, and BL2b may be formed in the first layer of metal (or M1 layer). For example, in the unit memory cell C1, the bit line BL1a can be electrically connected to the underlying contact strip MD1 through the conductive via CT1, and then the voltage signal can be transmitted to the drain or source of the unit memory cell C1, and the bit line BLIb can be electrically connected to the underlying contact strip MD2 through the conductive via CT2 and then the voltage signal can be transmitted to the doped region of the second portion FP2 of the unit memory cell C1.

The improved OTP memory structure of the present invention is compatible with fin field effect transistor (finFET) processes at 14 nm node or below and has better program efficiency. In addition, the application of the OTP memory array of the present invention not only has better programming efficiency, but also has the effect of reducing the unit memory cell area through the mirror symmetric design and the contact zone cutting area CMD, making the memory device able to have higher memory density.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A one-time programmable (OTP) memory structure, comprising:
a semiconductor substrate of a first conductivity type;
a fin disposed on the semiconductor substrate, wherein the fin extends along a first direction, wherein the fin comprises a first portion and a second portion that is contiguous with the first portion, and wherein the first portion and the second have different cross-sectional profiles; and
a gate extending over the fin along a second direction, wherein the gate partially overlaps with the first portion of the fin and partially overlaps with the second portion of the fin.

2. The OTP memory structure according to claim 1 further comprising:
a first gate dielectric layer between the gate and the first portion of the fin; and
a second gate dielectric layer between the gate and the second portion of the fin, wherein the first gate dielectric layer and the second gate dielectric have different thicknesses.

3. The OTP memory structure according to claim 2, wherein the first gate dielectric layer is thicker than the second gate dielectric layer.

4. The OTP memory structure according to claim 2, wherein a step is disposed between the first gate dielectric layer and the second gate dielectric layer.

5. The OTP memory structure according to claim 2, wherein the first gate dielectric layer is an input/output (I/O) oxide layer and has a thickness of 25-45 angstroms, and wherein the second dielectric layer is a core oxide layer and has a thickness of 5-25 angstroms.

6. The OTP memory structure according to claim 1, wherein the first portion of the fin has a first top width and the second portion of the fin has a second top width, wherein the first top width is greater than the second top width.

7. The OTP memory structure according to claim 1, wherein the first portion of the fin has the first conductivity type, and the second portion of the fin has a second conductivity type opposite to the first conductivity type.

8. The OTP memory structure according to claim 7, wherein the first conductivity type is P type and the second conductivity type is N type.

9. The OTP memory structure according to claim 1, wherein the first portion of the fin has a rectangular-shaped cross-sectional profile, and wherein the second portion of the fin has a conical tip-shaped cross-sectional profile and a sidewall surface with at least two different slopes.

10. The OTP memory structure according to claim 1, wherein the gate is a metal gate.

11. A one-time programmable (OTP) memory array, comprising:
a semiconductor substrate of a first conductivity type;
a plurality of fins disposed on the semiconductor substrate, wherein the plurality of fins extends along a first direction, wherein each of the plurality of fin comprises a first portion and a second portion that is contiguous with the first portion, and wherein the first portion and the second have different cross-sectional profiles; and
at least one gate extending over the plurality of fins along a second direction, wherein the plurality of gates gate partially overlaps with the first portion and partially overlaps with the second portion.

12. The OTP memory array according to claim 11 further comprising:
a first gate dielectric layer between the at least one gate and the first portion; and
a second gate dielectric layer between the at least one gate and the second portion, wherein the first gate dielectric layer and the second gate dielectric have different thicknesses.

13. The OTP memory array according to claim 12, wherein the first gate dielectric layer is thicker than the second gate dielectric layer.

14. The OTP memory array according to claim 12, wherein a step is disposed between the first gate dielectric layer and the second gate dielectric layer.

15. The OTP memory array according to claim 12, wherein the first gate dielectric layer is an input/output (I/O) oxide layer and has a thickness of 25-45 angstroms, and wherein the second dielectric layer is a core oxide layer and has a thickness of 5-25 angstroms.

16. The OTP memory array according to claim 11, wherein the first portion has a first top width and the second portion has a second top width, wherein the first top width is greater than the second top width.

17. The OTP memory array according to claim 11, wherein the first portion has the first conductivity type, and the second portion has a second conductivity type opposite to the first conductivity type.

18. The OTP memory array according to claim 17, wherein the first conductivity type is P type and the second conductivity type is N type.

19. The OTP memory array according to claim 11, wherein the first portion has a rectangular-shaped cross-sectional profile, and wherein the second portion of the fin has a conical tip-shaped cross-sectional profile and a sidewall surface with at least two different slopes.

20. The OTP memory array according to claim 11, wherein the at least one gate is a metal gate.
